(19) United States
(12) Patent Application Publication
(10) Pub. No.: US 2003/0224536 A1
(43) Pub. Date: Dec. 4, 2003

(54) Contact formation

(76) Inventors: Andreas Hilliger, Yokohama-shi (JP); Rainer Bruchhaus, Yokohama-shi (JP)

Correspondence Address: Horizon IP Pte Ltd, 166 Kallang Way, 6th Floor, Singapore, 349249, SG

(21) Appl. No.: 10/161,863

(22) Filed: Jun. 4, 2002

(51) Int. Cl. H01L 21/00

(52) U.S. Cl. 438/3

(57) ABSTRACT

An improved process for forming a contact on a top electrode of a capacitor is described. The process includes forming an encapsulation layer on at least the top electrode of the capacitor. When the contact hole is etched, the encapsulation layer is not removed. After the contact hole is formed, the resist mask is removed. Since the encapsulation layer remains on the top electrode, the capacitor is protected from hydrogen resulting from the decomposition of the resist material.

### FIELD OF THE INVENTION

The present invention relates generally to fabricating contacts for capacitors. More particularly, the invention relates to fabricating contacts for ferroelectric capacitors without degrading the properties of the ferroelectric layer.

### BACKGROUND OF THE INVENTION

FIG. 1 shows a conventional ferroelectric memory cell 101 having a transistor 130 and a ferroelectric capacitor 140. The capacitor comprises a ferroelectric ceramic thin film sandwiched between first and second electrodes 141 and 142. Electrode 142 is coupled to a plateline 170 and electrode 141 is coupled to the transistor which selectively couples or decouples the capacitor from a bitline 160, depending on the state (active or inactive) of a wordline 150 coupled to the transistor gate. A plurality of cells are interconnected by platelines, bitlines, and wordlines to form an array.

The ferroelectric memory stores information in the capacitor as remanent polarization. The logic value stored in the memory cell depends on the polarization of the ferroelectric capacitor. To change the polarization of the capacitor, a voltage which is greater than the switching voltage (coercive voltage) needs to be applied across its electrodes. An advantage of the ferroelectric capacitor is that it retains its polarization state after power is removed, resulting in a non-volatile memory cell.

To realize high-density integrated circuits (ICs), a capacitor over plug (COP) structure is employed. FIG. 2 shows a conventional COP structure 201. The COP structure is formed on a substrate 205 and insolated by an interlevel dielectric (ILD) layer 270. The COP structure includes a capacitor 140 having a ferroelectric layer 246 located between first and second electrodes 141 and 142. The first electrode is coupled to, for example, a diffusion region of a transistor via a plug 265 while the second electrode is coupled to a plateline via a contact formed in a contact hole 268.

Referring to FIG. 3, the formation of the contact hole is shown. A photoresist layer 340 is deposited over the dielectric layer and selectively patterned to form an opening therein, exposing a portion of the dielectric layer. The contact opening 365 is then created by anisotropically etching the dielectric layer to remove the portion exposed by the resist layer. The resist layer is removed after the via is created. During the removal process, the decomposition of the resist produces hydrogen and other by-products. The hydrogen diffuses through the electrode and degrades the ferroelectric properties of the ferroelectric layer.

An anneal is preformed to repair the damage caused by the hydrogen. Typically, the anneal is performed at a temperature of about 650° C. for about 60 minutes. However, exposing the structure to such high temperatures for such a long period of time adversely impacts the underlying structures as well as increasing manufacturing costs.

From the foregoing discussion, it is desirable to avoid degrading the properties of the ferroelectric layer caused by hydrogen which is produced during resist removal.

### SUMMARY OF THE INVENTION

The invention relates generally to the formation of contacts in integrated circuits. In one embodiment, the invention relates to forming a contact which is coupled to a top electrode of a capacitor. The capacitor includes a dielectric layer between top and bottom electrodes. In one embodiment, the capacitor comprises a ferroelectric capacitor. An encapsulation layer is formed at least over the top electrode of the capacitor. Above the capacitor is an interlevel dielectric layer. A resist mask having an opening corresponding to the location in which the contact is to be formed is provided over the interlevel dielectric layer. The dielectric layer is etched to create the contact opening without removing the encapsulation layer. The resist mask is removed. Hydrogen produced during the removal of the resist mask is prevented from diffusing into the capacitor by the encapsulation layer. By avoiding damage to the capacitor caused by hydrogen, the anneal which is conventionally performed after contact hole formation can be eliminated, or at least reduced (e.g. lower temperature and/or shorter duration).

### BRIEF DESCRIPTION OF DRAWINGS

FIG. 1 shows a ferroelectric memory cell;

FIG. 2 shows a cross-sectional view of a capacitor on plug structure;

FIG. 3 shows a conventional process for forming a capacitor contact.

FIGS. 4-8 show a process for forming a capacitor contact in accordance with one embodiment of the invention.

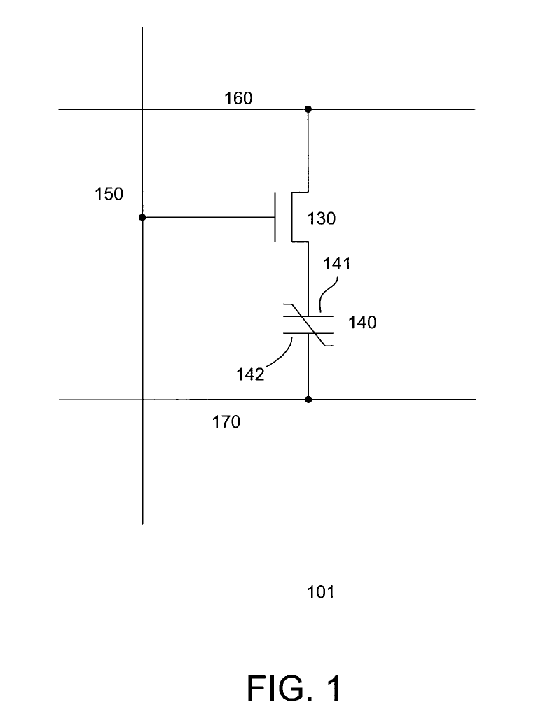

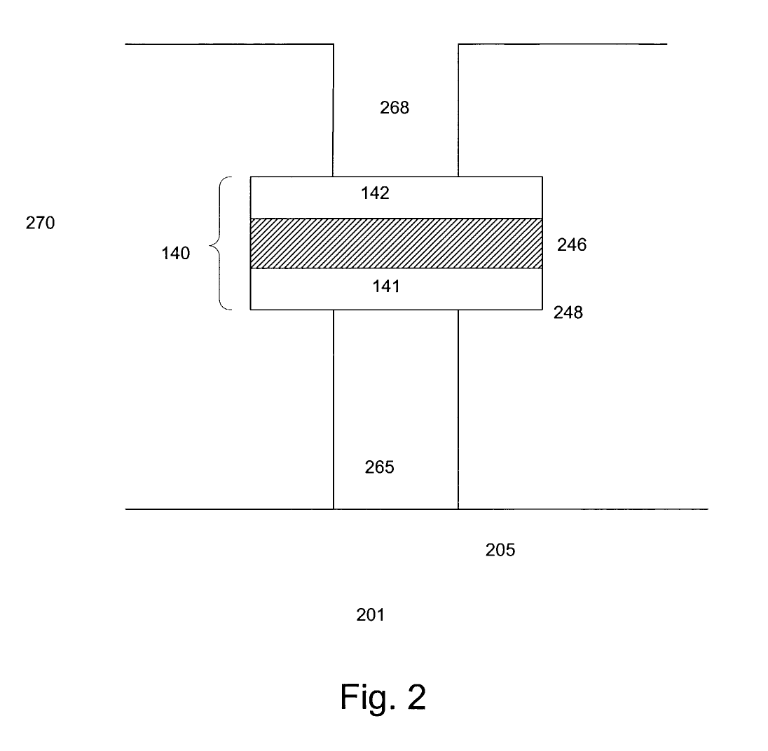

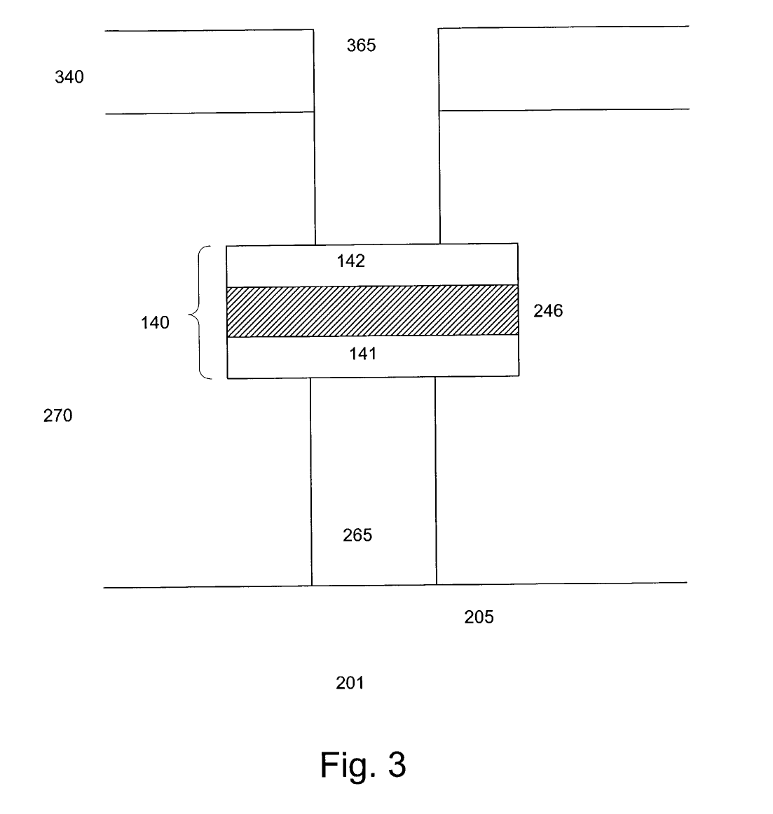

### DETAILED DESCRIPTION OF THE INVENTION

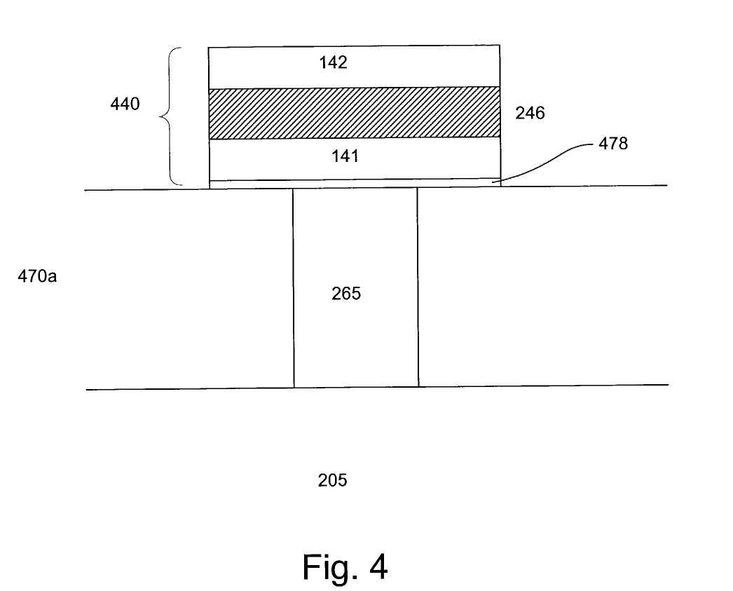

FIGS. 4-8 show a process for forming a capacitor contact in accordance with one embodiment of the invention. Referring to FIG. 4, a capacitor 440 is provided on a substrate 205. As shown, a COP structure is provided. Other types of capacitor structures are also useful. The COP structure, as shown, is formed using conventional techniques.

In one embodiment, an ILD layer 470a is deposited on the substrate. The ILD layer comprises, for example, silicon oxide. Other types of dielectric materials, such as silicon nitride or doped silicate glass are also useful. A conductive plug 265 is then formed in the ILD layer, contacting a diffusion region of a transistor. The plug is formed from, for example, polysilicon or tungsten. Other types of conductive materials are also useful. The capacitor 440 is then formed on the ILD layer. In one embodiment, first electrode 141, ferroelectric 246, and second electrode 142 layers are deposited on the ILD layer. In one embodiment, the electrode comprises a noble metal, such as platinum. Other types of conductive materials such as iridium, iridium oxide, strontium ruthenium oxide or ruthenium oxide can also be used. The ferroelectric layer comprises, for example, lead zirconate titanate (PZT). Other types of ferroelectric materials, such as strontium bismuth tantalate (SBT), can also be used.

A conductive barrier layer 478 can be provided beneath the first electrode to prevent or inhibit the diffusion of oxygen to the plug. The barrier layer, for example, comprises iridium. Iridium oxide, ruthenium oxide, or other types of barrier materials can also be used. An adhesion layer, such as titanium or titanium nitride, can be provided on the ILD layer to promote adhesion between the ILD and barrier layer. The various layers are then patterned to create the capacitor. Depending on the application, the various layers can be patterned together or separately. For example, the lower portion of the capacitor can be formed first by patterning the first or bottom electrode and layers below. After the lower capacitor portion is formed, the ferroelectric and second or top electrodes are deposited and patterned to complete the capacitor. Forming the capacitor in two separate steps is particularly useful for chained memory cell architectures, as described in, for example, Takashima et al., “High Density Chain Ferroelectric Random Access Memory (chain FRAM)”, IEEE Jrnl. of Solid State Circuits, vol.33, pp.787-792, May 1998, which is herein incorporated by reference for all purposes.

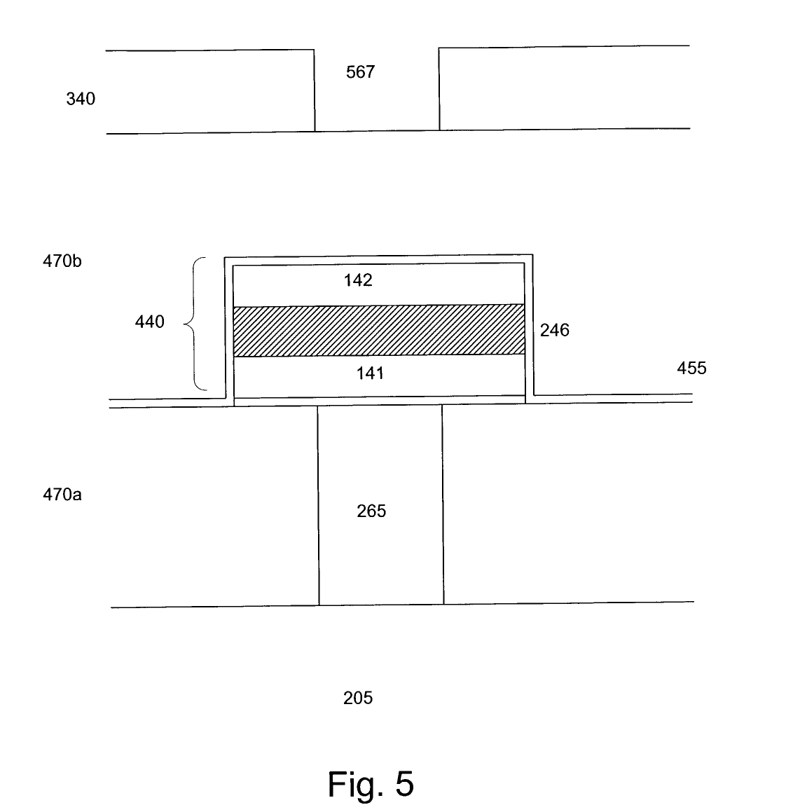

Referring to FIG. 5, an encapsulation layer 455 is deposited over the capacitor. In one embodiment the encapsulation layer comprises a non-conductive material which prevents or inhibits the diffusion of hydrogen. In one embodiment, the encapsulation layer comprises aluminum oxide. Other encapsulation materials, such as titanium oxide or zirconate oxide, are also useful. The encapsulation layer is deposited using conventional techniques, such as sputtering or metal organic chemical vapor deposition (MOCVD).

Alternatively, the encapsulation layer comprises a conductive material, such as iridium oxide. Other types of conductive materials which sufficiently inhibit diffusion of hydrogen, for example titanium nitride, are also useful. In such applications, the conductive barrier layer is provided only on top of the second electrode. In one embodiment, the conductive encapsulation layer is deposited over the second electrode. The various layers are then patterned to create the capacitor. An ILD layer 470b is deposited over the substrate, covering the capacitor structure. The ILD layer comprises, for example, silicon oxide. Other types of dielectric materials, for example silicon nitride or doped silicate glass, are also useful. The ILD layer is deposited by conventional techniques. Above the ILD layer is deposited a photoresist layer which selectively patterned to form an opening 567. The resist layer is deposited and patterned using conventional techniques.

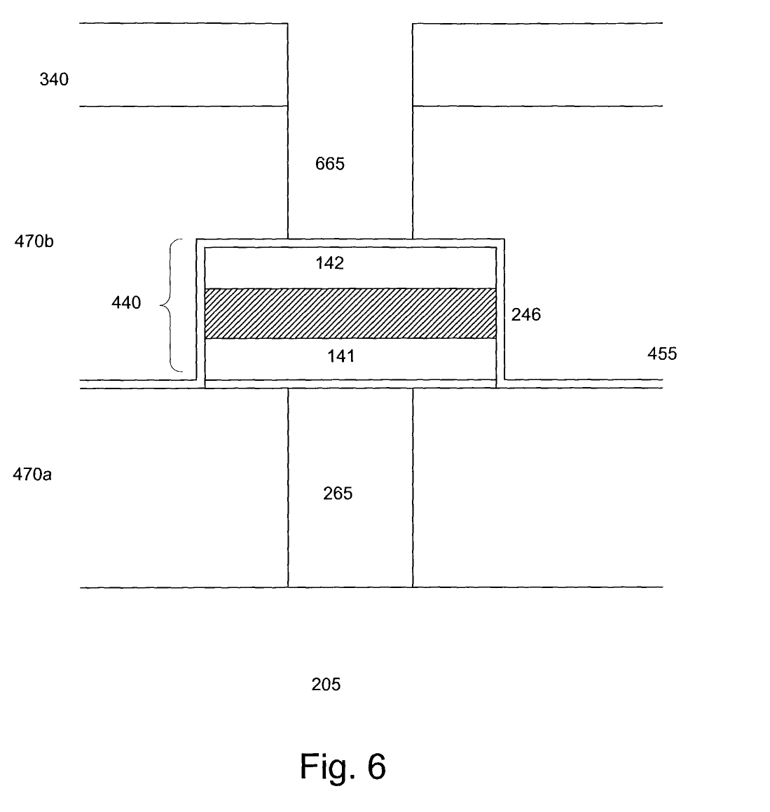

Referring to FIG. 6, the portion of the dielectric layer exposed by the opening is removed by an anisotropic etch, such as an RIE to form via opening 665. In one embodiment, the etch removes the dielectric material while leaving the encapsulation layer covering the second electrode. This can be achieved by choosing an etch chemistry which etches the dielectric material selectively to the encapsulation material. Alternatively, a timed etch can be used, stopping when the encapsulation layer is reached.

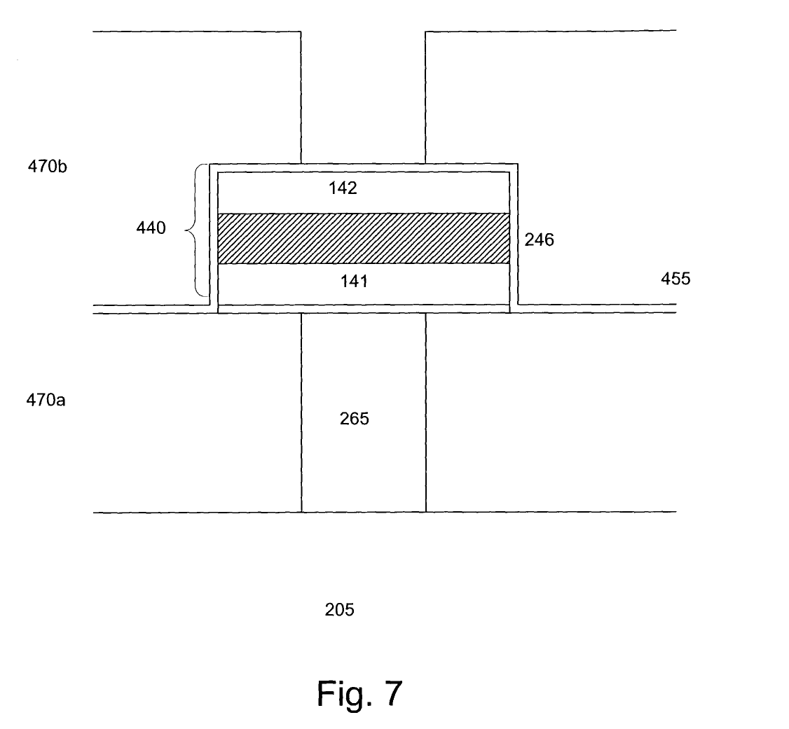

As shown in FIG. 7, the resist is removed by, for example, ashing after via opening is formed. Other techniques for removing the resist layer can also be used. Since the encapsulation layer protects the capacitor, diffusion of hydrogen formed during the decomposition of the resist to the ferroelectric layer is inhibited or prevented. As such, degradation of the ferroelectric layer due to hydrogen contamination is avoided or reduced. Since damage to the capacitor is reduced or eliminated, the need for a high temperature anneal to repair the capacitor damage is correspondingly reduced and eliminated. Thus the detrimental effects from the high temperature anneal is reduced or avoided.

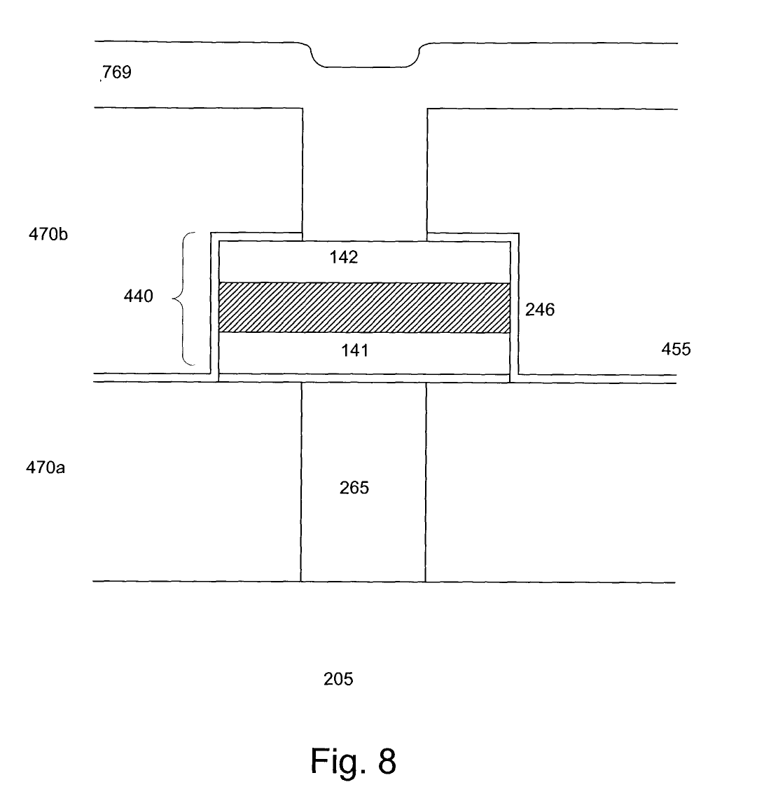

Referring to FIG. 8, the encapsulation layer is removed to expose the second electrode. A conductive layer 769 is deposited, filling the opening. In alternative embodiments using a conductive encapsulation layer, removal of the barrier layer prior to depositing the conductive layer to fill the via opening is not necessary. The conductive layer is then planarized by, for example, chemical mechanical polishing (CMP) to remove excess conductive material from the surface of the dielectric layer, thus forming a contact plug. The process continues to complete the fabrication of the IC.

While the invention has been particularly shown and described with reference to various embodiments, it will be recognized by those skilled in the art that modifications and changes may be made to the present invention without departing from the spirit and scope thereof. The scope of the invention should therefore be determined not with reference to the above description but with reference to the appended claims along with their full scope of equivalents.

What is claimed is:

1. A process for fabricating an integrated circuit comprising:
providing a substrate having a capacitor formed thereon, the capacitor includes a dielectric layer between top and bottom electrodes;
forming an encapsulation layer over at least the second electrode;
depositing an interlevel dielectric layer over the capacitor;
forming a photoresist mask over the dielectric layer, the resist mask includes an opening corresponding to a location a contact hole is to be formed;
etching the contact in the dielectric layer to expose second electrode without removing the encapsulation layer; and
removing the resist mask, the encapsulation layer protects the capacitor from hydrogen formed during the removal of the resist mask.

2. The process of claim 1 wherein the dielectric layer comprises a ferroelectric material.

3. The process of claim 2 wherein the ferroelectric material comprises PZT.

4. The process of claim 2 wherein the integrated circuit comprises a ferroelectric memory integrated circuit.

5. The process of claim 1 wherein the integrated circuit comprises a memory integrated circuit.

6. The process of claim 1 wherein the dielectric layer comprises a high dielectric constant dielectric material.

7. The process of claim 6 wherein the integrated circuit comprises a memory integrated circuit.

8. The process of claim 1 wherein the encapsulation layer inhibits the diffusion of hydrogen.

9. The process of claim 8 wherein the encapsulation layer comprises a conductive material.

10. The process of claim 9 further comprising, after removing the resist mask, filling the contact opening with a second conductive material to form a contact.

11. The process of claim 9 wherein the conductive material comprises iridium oxide.

12. The process of claim 11 further comprising, after removing the resist mask, filling the contact opening with a second conductive material to form a contact.

13. The process of claim 9 wherein the capacitor is formed by:
depositing a conductive bottom electrode layer on the substrate;
patterning the conductive bottom electrode layer to form the bottom electrode;
depositing the dielectric layer;
depositing a conductive top electrode layer; and
patterning the conductive top electrode and dielectric layers.

14. The process of claim 13 further comprising, after removing the resist mask, filling the contact opening with a second conductive material to form a contact.

15. The process of claim 8 wherein the encapsulation layer comprises a non-conductive material.

16. The process of claim 15 further comprising:
after removing the resist mask, removing the encapsulation layer at a bottom of the contact opening to expose the top electrode; and
filling the contact opening with a second conductive material to form a contact.

17. The process of claim 15 wherein the non-conductive material comprises aluminum oxide.

18. The process of claim 17 further comprising:
after removing the resist mask, removing the encapsulation layer at a bottom of the contact opening to expose the top electrode; and
filling the contact opening with a second conductive material to form a contact.

19. The process of claim 15 wherein the capacitor is formed by:
depositing a conductive bottom electrode layer on the substrate;
patterning the conductive bottom electrode layer to form the bottom electrode;
depositing the dielectric layer;
depositing a conductive top electrode layer; and
patterning the conductive top electrode and dielectric layers.

20. The process of claim 19 further comprising:
after removing the resist mask, removing the encapsulation layer at a bottom of the contact opening to expose the top electrode; and
filling the contact opening with a second conductive material to form a contact.
